(19) United States
(12) Patent Application Publication
(10) Pub. No.: US 2023/0337399 A1
(43) Pub. Date: Oct. 19, 2023

(54) AN ELECTRONIC DEVICE WITH A THERMAL MANAGEMENT SYSTEM INCLUDING A GRAPHITE ELEMENT

(71) Applicant: NEOGRAF SOLUTIONS, LLC, Lakewood, OH (US)

(72) Inventors: Jonathan TAYLOR, Mayfield Village, OH (US); Greg KRAMER, Twinsburg, OH (US); Chad FINKBEINER, Highland Heights, OH (US); Robert A. REYNOLDS, Bay Village, OH (US)

(73) Assignee: NEOGRAF SOLUTIONS, LLC, Lakewood, OH (US)

(21) Appl. No.: 18/044,033

(22) PCT Filed: Sep. 3, 2021
(86) PCT No.: PCT/US2021/048979

§ 371 Date: Mar. 3, 2023

Related U.S. Application Data
(60) Provisional application No. 63/074,876, filed on Sep. 4, 2020.

(51) Int. Cl. H05K 7/20

(52) U.S. Cl. CPC H05K 7/2039

(57) ABSTRACT

An electronic device having a thermal management system is provided. The thermal management system has a monolithic graphite element having a thickness of at least 150 microns. The graphite element has a thermal conductivity of at least about 700 W/mK. The graphite element is devoid of an internal adhesive, i.e., the graphite element is monolithic. The thermal management system is in operative contact with a heat source which comprises more than one electronic component. Preferably, the more than one electronic component is disposed on a stacked motherboard.

### CROSS-REFERENCE TO RELATED APPLICATIONS

This application claims priority to and the benefit of U.S. Provisional Patent Application No. 63/074,876, filed on Sep. 4, 2020, the entire contents of which are incorporated herein by reference.

### BACKGROUND

With the internet of things (IoT), electronic devices have become a ubiquitous part of everyday life, especially portable electronic devices. Where once everyone had keys, now all of us have mobile (cellular) telephones. Similar to the keys of old, our mobile phones are our access point for our work as well as many of our leisure time activities.

As mobile phones have become more and more a hub of activities, the capabilities of such phones have dramatically increased. Since 2007 “smart” mobile phones have become common place and replaced mobile phones that were just for phone calls, texting and emails. As for such capabilities, mobile phones can now be used to have global video conferences, watch the latest movie as well as have goods and/or services brought to your door from all corners of the globe. The devices themselves have changed to including multiple displays, high resolution cameras as well as being foldable.

### BRIEF SUMMARY

Disclosed herein is an electronic device. The device will be described in terms of a portable electronic device such as a mobile phone, laptop or tablet, however the technology is applicable to any type of electronic device in which thermal management of more than one electronic component is needed and passive instead of active cooling is preferred or required.

Active cooling is defined cooling technology which uses a cooling medium to transfer heat such as a heat pipe, a vapor chamber or a fan, just to provide a few examples. Passive cooling does not include a cooling medium nor is it a forced convection system.

In accordance with aspects of the present disclosure, an electronic device having a thermal management system is provided. The thermal management system has a monolithic graphite element having a thickness of at least 150 microns. The graphite element has a thermal conductivity of at least about 700 W/mK. The graphite element is devoid of an internal adhesive (also may be referred to as a binder). The thermal management system is in operative contact with a heat source which comprises more than one electronic component. Preferably the more than one electronic component is disposed on a stacked motherboard.

In accordance with aspects of the present disclosure, an electronic device having a graphite element in operative contact with a heat source is provided. The heat source comprises more than one electronic component, disposed on a stacked motherboard. The graphite element is preferably a monolithic graphite element having a thickness of at least about 150 microns. The graphite element has a thermal conductivity of at least about 700 W/mK. The graphite element is devoid of an internal adhesive (also may be referred to as a binder). A preferred type of graphite is flexible graphite. The device may have a thickness of no more than 15 mm.

In accordance with aspects of the present disclosure an electronic device comprising a thermal management system including a flexible graphite element having a thickness of at least about 150 microns and a thermal conductivity of at least about 700 W/mK is provided. Preferably the flexible graphite element is devoid of an internal adhesive. The thermal management system may be devoid of an additional heat dissipation element. Further the thermal management system is in operative contact with a heat source. The heat source comprises more than one electronic component; wherein the more than one electronic component is disposed on a stacked motherboard.

Unless otherwise indicated, “operative contact” is used herein to mean heat is dissipated from the heat source into the thermal management system and in particular into the graphite element. Unless otherwise indicated, “direct operative contact” is used herein to mean physically adjacent to or touching in a manner such that operative contact can be established.

The foregoing aspects of the present disclosure are equally applicable to all of the below types of electronic devices and others irrespective of the electronic device being portable or not.

### BRIEF DESCRIPTION OF THE DRAWINGS

FIG. 1 is a schematic view of an embodiment disclosed herein.

FIG. 2 is an internal view of the Device used in the Example without the back cover.

FIG. 3a. is an internal view of Device including the test sample disclosed in the

FIG. 3b is an internal view of the Device including the VC control disclosed in the Example.

FIG. 4 is a chart of screen temperature for both normal operation (“no”) and charging (“yes”)

FIG. 5 is a chart of the performance results for both normal operation (“no”) and charging (“yes”)

FIG. 6 is a chart of results for dissipating heat form the CPU for both normal operation (“no”) and charging (“yes”)

FIG. 7 is a chart of results for dissipating heat form the GPU for both normal operation (“no”) and charging (“yes”)

### DETAILED DESCRIPTION

The present disclosure is directed to electronic devices. Such electronic devices include portable as well as stationary electronic devices. Examples of such devices include mobile phones, tablets, laptops, and wearables. These devices include foldable devices. The applicable devices also include devices which have a user interface on at least two major surfaces of the device (e.g., the Nubia X Phone). A phone with a second user interface may be referred to as a phone with a rear screen. In accordance with the present disclosure, the electronic devices may have a first user interface on a first major surface of the device and a second user interface on a second major surface of the device. The embodiments are equally applicable to components of a vehicle or other modes of transportation.

The thermal management systems of the present disclosure are particularly advantageous to an electronic device having a thickness of no more than 15 mm, preferably no more than 12.5 mm. A preferred thickness is no more than 10 mm. A non-limiting exemplary range of preferred thickness for the device ranges from about less than 15 mm to about 5 mm. Particular devices that fall in this range include mobile telephones, tablets, portable gaming systems, household items, IoT devices, and wearable devices such as watches and/or medical devices.

A thermal management system which is applicable to above devices includes a flexible graphite element having a thickness of at least about 150 microns. The graphite element has an in-plane thermal conductivity of at least about 700 W/mK. The graphite element is devoid of an internal adhesive; the lack of an adhesive may also be referred to as binderless. The thermal management system is in operative contact with a heat source which comprises more than one electronic component. Preferably, the more than one electronic component is disposed on a stacked motherboard. The graphite element can be referred to as “monolithic”.

In another aspect of the present disclosure, the thermal management system applicable to the above electronic devices includes a graphite element in operative contact with a heat source. The heat source includes more than one electronic component, disposed on a stacked motherboard. The graphite element is preferably a monolithic graphite element having a thickness of at least about 150 microns. The graphite element has an in-plane thermal conductivity of at least about 700 W/mK. The graphite element may be devoid of an internal adhesive. A preferred type of graphite is flexible graphite. Preferably, the device has a thickness of no more than 15 mm. The device may have a thickness of no more than 10 mm.

Another aspect of the present disclosure is an electronic device comprising a thermal management system including a graphite element having a thickness of at least about 150 microns and a thermal conductivity of at least about 700 W/mK. The graphite element may be a flexible graphite element. Preferably the flexible graphite element is devoid of an internal adhesive. The thermal management system may be devoid of an additional heat dissipation element. Further the thermal management system is in operative contact with a heat source. The heat source may be a heat source in the electronic device. The heat source may comprise more than one electronic component; wherein the more than one electronic component is disposed on a stacked motherboard.

The above general embodiments are further described below. The below description is applicable to each and every one of the above general embodiments.

Regarding the graphite element, the preferred type of graphite is flexible graphite. A suitable example of the flexible graphite is NeoNxGen® flexible graphite (“NNG”) available from NeoGraf Solutions, LLC of Lakewood, Ohio U.S.A. Suitable grades of NNG include N-150, N-200, N-250, N-270 and N-300 as well as the P series grades such as P-150 and P-200. Suitable flexible graphite may have a density within the range of 1.75 g/cm³ to 2.15 g/cm³, including 1.85 g/cm³ to 2.10 g/cm³, 1.90 g/cm³ to 2.10 g/cm³, and 1.95 g/cm³ to 2.05 g/cm³. Suitable flexible graphite may have an electromagnetic interference (EMI) shielding effectiveness at a frequency up to 6 GHz of at least 100 dB, including at least 150 dB, at least 200 dB, at least 225 dB, and at least 250 dB.

The graphite element comprises a single piece of graphite. This may also be referred to as a monolithic piece of graphite. This may further be alternatively stated as the graphite element is not composed of two (2) or more pieces of graphite adhered together through the use of an adhesive or binder or the graphite element is devoid of adhesive or binder.

The graphite element has a thickness of at least about 150 microns. Other exemplary thicknesses include at least about 175 microns, at least about 200 microns, at least about 250 microns, and at least about 300 microns. In some applications the thickness of the graphite element may be limited to about 500 microns, but this limitation is not applicable to all applications.

The graphite element has an in-plane thermal conductivity of at least about 700 W/mK. If so desired, the graphite element may have a thermal conductivity of at least about 800 W/mK; a further exemplary thermal conductivity comprises about 1000 W/mK or more. Another preferred thermal conductivity comprises about 1100 W/mK or more.

A thru-plane thermal conductivity of the graphite element is less than about 6 W/mK, preferably less than about 5 W/mK.

The graphite element has a diffusivity of at least about 3.8 cm²/s, including more than 3.8 cm²/s, preferably at least about 4 cm²/s. A non-limiting example of a preferred range of the diffusivity includes from about 5 to 10 cm²/s.

Optionally, the graphite element of the thermal management system may have a protective coating on one or more of its exterior surfaces. One example of suitable type of coating is a PET film.

Another optional element is that the graphite element may have an adhesive applied to one or both of the major surfaces of the graphite element. An application of the adhesive applied to the graphite element may be used to adhere the graphite element to the heat source. A further optional embodiment is that the adhesive is used to adhere the graphite element to just one or more of the electronic components which makes up the heat source. A further optional embodiment, the graphite element may include both of one or more surfaces of the graphite element coated with the protective coating and the adhesive as an exterior coating of the thermal management system to adhere the system to the heat source. The embodiments disclosed herein are not limited to the afore optional components; other optional components may be included as desired.

Optionally the thermal management systems disclosed herein are devoid of one or more fins. It is preferred that the thermal management system has a substantially planar main body and is devoid of a portion of the thermal management system extending away from the planar main body in a direction outside of the plane of the main body.

Other optional configurations include that it is preferable that the thermal management system is devoid of a fan, heat pipe and/or a vapor chamber. In these embodiments its preferred that the thermal management system is devoid of an active cooling element or an active cooling medium.

Optionally, a surface area of a portion of the thermal management system adjacent the heat source is larger than a surface area of the heat source which is in operative contact with the thermal management system. Further, this is equally applicable to the graphite element, in that the graphite element has a larger surface area than the surface area of the heat source in operative contact with the thermal management system. Further specific aspects in accordance with the thermal management system and/or graphite element of the present disclosure include having a first major surface adjacent to the heat source in operative contact with the heat source. The first major surface having a first portion is in direct operative contact with heat source and a second portion is not in direct operative contact with the heat source. A surface area of the second portion is larger than a surface area of the heat source. Alternatively, the surface area of the second portion comprises at least ten (10%) percent of the surface area of the heat source. A further alternative, the surface area of the second portion comprises at least twenty-five (25%) percent of the surface area of the heat source. A further alternative, the surface area of the second portion comprises at least fifty (50%) percent of the surface area of the heat source. A further alternative, the surface area of the second portion comprises at least seventy-five (75%) percent of the surface area of the heat source. A further alternative, the surface area of the second portion comprises substantially the same surface area of the heat source or about 100% of the surface area of the heat source. A further alternative, the surface area of the second portion comprises substantially the same surface area of the motherboard or about 100% of the surface area of the motherboard. In a third configuration the surface area of the second portion may be smaller than the surface area of the heat source.

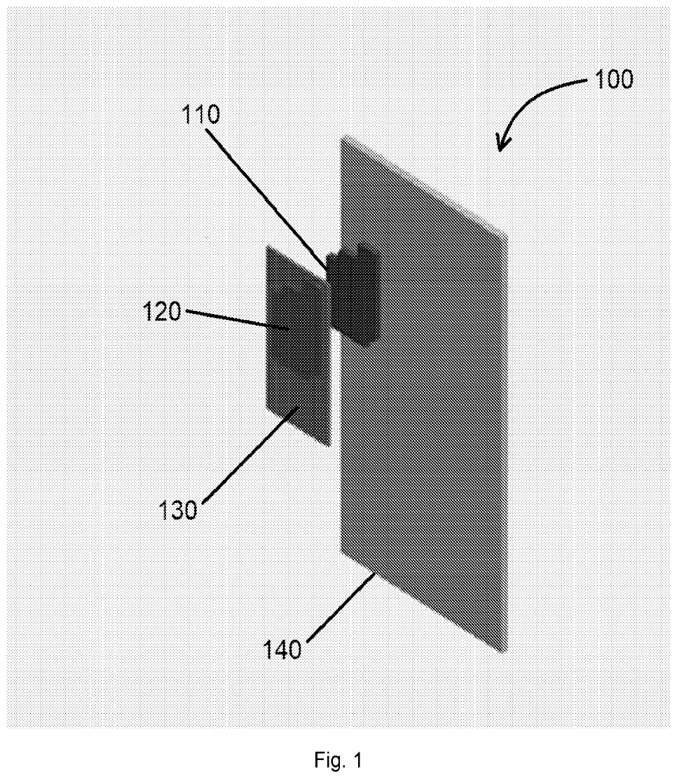

Illustrated in FIG. 1 is an electronic device 100 of the present disclosure comprising thermal management system 110 (“Heat Spread”) has about the same surface area as the “Heat Source” 120. In this embodiment the heat source 120 may include a stacked motherboard 130. As shown the stacked motherboard 130 comprises a printed circuit board having at least one (1) chip such as a GPU on one (1) side of the motherboard 130 and at least a second chip such as a CPU (not shown) on the other side of the motherboard 130, thereby forming the Heat Source 120 (any at least two (2) chips may be used to form the motherboard 130). Any one of the thermal management systems (110) described herein is disposed in operative contact with the heat source 120. The thermal management system 110 may be adhered to the heat source 120, for example, the thermal management system may be adhered to at least one of the electronic components of the heat source 120. As shown in FIG. 1, the thermal management system 110 (Heat Spread) has substantially the same surface area as the chip generating the heat (i.e., Heat Source). Additionally, the thermal solution may be disposed on the mid-plate 140 (also referred to as the “Chassis”) of the device. If so, the chosen thermal management system may be adhered to the mid-plate 140 also. This may be accomplished with or without a gap pad (not shown).

The thermal management systems of the present disclosure are used to make an electronic device which minimizes touch temperature, which may also be referred to as the surface temperature, of the device. One standard for defining surface temperature is ASTM C1055. A summary of the standard cited in the September 2016 version of Electronics Cooling Magazine is provided below:

ASTM C1055 (the Standard Guide for Heated System Surface Conditions that Produce Contact Burn Injuries) recommends that surface temperatures remain at or below 140° F. The reason for this is that the average person can touch a 140° F. surface for up to five seconds without sustaining irreversible burn damage.

| | | Tissue | | | |
|---|---|---|---|---|---|
| | | Temperature | | | |
| Sensation | Skin Color | deg. C. | deg. F. | Process | Injury |
| Numbness | White | 72 | 162 | Protein | Irreversible |
| | | 68 | 140 | Coagulation | |
| | Mottled | 64 | 111 | Thermal | Possibly |
| | Red and White | 60 | 93 | Inactivation of | Reversible |
| Maximum Pain | Bright Red | 56 | | Tissue Contents | Reversible |
| Severe Pain | Light Red | 52 | | | |
| Threshold Pain | | 48 | | | |
| Hot | Flushed | 44 | | Normal | None |
| Warm | | 40 | | Metabolism | |
| | | 36 | | | |
| | | 32 | | | |

Per ASTM C1055, it is further preferable for the electronic device to operate with a surface a temperature below 44° C. (˜111° F.), which is identified as the threshold for pain (beyond just being “hot”). For comparison sake, in the same article the temperature of 46° C., is cited as an extremely high-risk level by OSHA. The thermal management systems disclosed herein can be incorporated into an electronic device for the device to operate below the pain threshold.

Advantages that may be realized by using the thermal management systems disclosed herein include one or more of the following: (1) ease of use, simplified manufacturing of the thermal management system; (2) thermal management system includes less inactive components such as internal adhesive layers and/or other insulative materials; (3) ease of installation of the thermal management system; (4) thermal management system does not have a shelf life and (5) the thermal management system does not rely on a working medium e.g., latent heat of vaporization/condensation of vapor chamber medium. A further benefit is that the thermal management system may have a thickness of more than 200 microns and a thermal conductivity of at least 1000 W/mK in-plane thermal conductivity.

### EXAMPLE

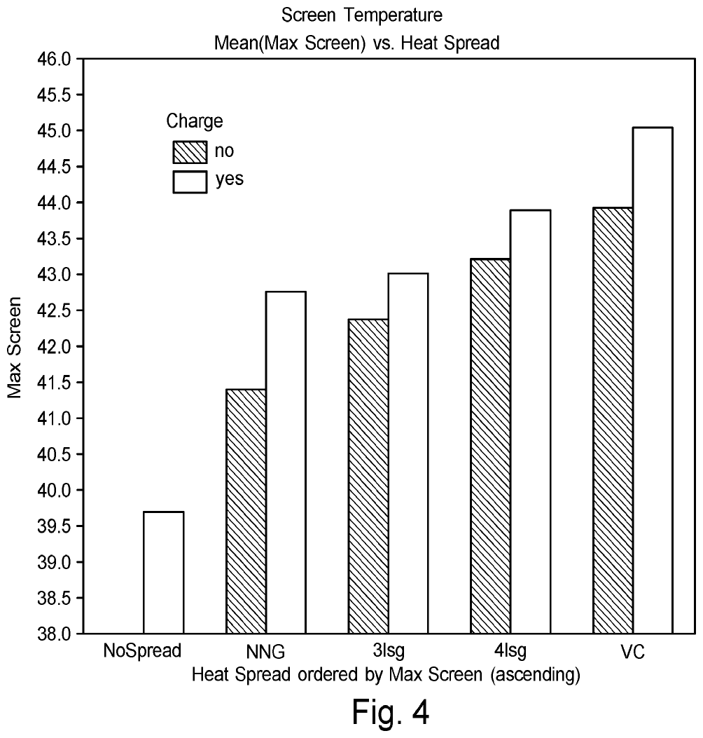

A Samsung Note 10 cellular telephone (“Device”) was used to evaluate thermal management systems disclosed herein relative to contemporaneous commercially available thermal management systems (“OEM thermal management systems”). The OEM thermal management systems included one embodiment with a vapor chamber in thermal contact with GPU & CPU on the motherboard. The vapor chamber is adjacent a mid-plate (chassis) on this embodiment. On the side opposing the vapor chamber is a stacked motherboard which includes the GPU and the CPU. The motherboard was fully shielded. This embodiment is identified as “VC” FIGS. 4-7. Other commercial options tested include a 3 layer stack-up of 70 micron synthetic graphite identified as “3/sg” in FIGS. 4-7, and a 4 layer stack-up of 70 micron synthetic graphite identified as “4/sg” in FIGS. 4-7. An adhesive was used in between each layer of the 3/sg and 4/sg thermal management systems. All three (3) alternatives are a control or collectively “the controls.” Each control was adhered to the motherboard during its testing.

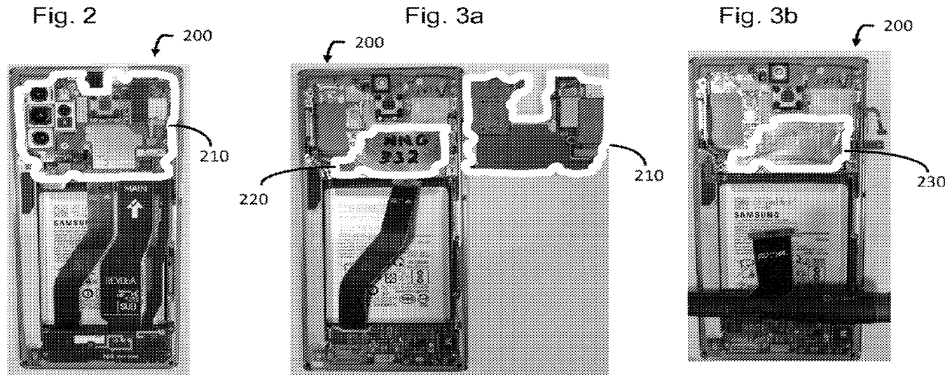

The Device 200 with the back cover removed is shown in FIG. 2, which shows the motherboard 210. In FIG. 3a the motherboard 210 was removed and placed to the right of the Device 200. An embodiment of the thermal management system (“test sample”) 220 described herein was placed in the Device 200 at a location that it would be in operative contact with the motherboard. The test sample had substantially the same surface area as the corresponding heat source on the motherboard. FIG. 3b shows the Device 200 set up as the VC control embodiment with the motherboard 210 and vapor chamber heat spread 230.

The test sample included a graphite element comprising a 270 micron thick grade of NeoNxGen® flexible graphite available from NeoGraf Solutions, LLC of Lakewood, Ohio. The graphite element of test sample had an in-plane thermal conductivity of at least about 1100 W/mK and a thru-plane thermal conductivity of less than about 5 W/mK. The test sample further included a plastic layer on each major surface and an adhesive on one side to adhere the test sample to the mother board. The test sample had an overall thickness of about 330 microns. The test sample is identified as “NNG” in FIGS. 4-7.

The variables tested included the dissipation of heat from the GPU or the CPU as well as the surface temperature of the screen of the Device as well as the overall performance of the Device. These variables were tested during normal operation of the Device (shown as “no” in FIGS. 4-7) as well as when the Device was being charged (shown as “yes” in FIGS. 4-7).

UL's 3DMark-Slingshot Extreme was chosen for testing as it is a widely-accepted benchmark used to score the physics (CPU) and graphics (GPU) of high-end smartphones. In order to achieve steady-state test results, the Professional Version of 3DMark was purchased and installed on the Device to enable infinite looping of the 90-second Slingshot Extreme benchmark test. All testing was conducted in a still air environment with tightly controlled ambient temperature and humidity. Parameters available for measuring include surface point temperatures via thermocouples, images via IR camera (Fluke, Model Ti55), internal component temperatures (CPU, GPU, etc.) via built-in thermistors, CPU and GPU clock frequencies, and system performance via Slingshot Extreme benchmark score. The version used was the Open GL ES3.1.

In each instance, the thermal management system, was used in the same location as the OEM control containing the vapor chamber (VC). The thermal management system was in thermal communication with both of the GPU or the CPU (“heat source”). In addition to the above, the embodiment may further be described as the screen of the phone, the mid-plate below the screen, the thermal management system was located adjacent the mid-plate. The thermal interface was used to place the thermal management system in thermal contact with the GPU and CPU on the motherboard. The backside of the motherboard was covered by a plastic cover. Adjacent the plastic cover was the wireless charger. The wireless charger was also adjacent to the back cover of the Device.

FIG. 4 is a chart of the performance of the test sample, the three (3) control samples, and a sample with no thermal management solution (identified as “NoSpread”) testing the variable of surface temperature of the screen over several runs. The test sample was the only embodiment in which for each test, as well as the mean, screen temperature stayed below 44° C., this was true for both normal operation as well as during charging. The test samples were the only experiments for which the screen temperature was below the pain threshold. Surprisingly, the three (3) layer synthetic graphite control (3/sg) was better at minimizing the screen temperature than the four (4) layer synthetic graphite control (4/sg). It also interesting that the vapor chamber control (VC) exhibited the worst performance at reducing the screen temperature. Conventional wisdom is that active cooling such as the vapor chamber will out-perform passive cooling such as the test samples.

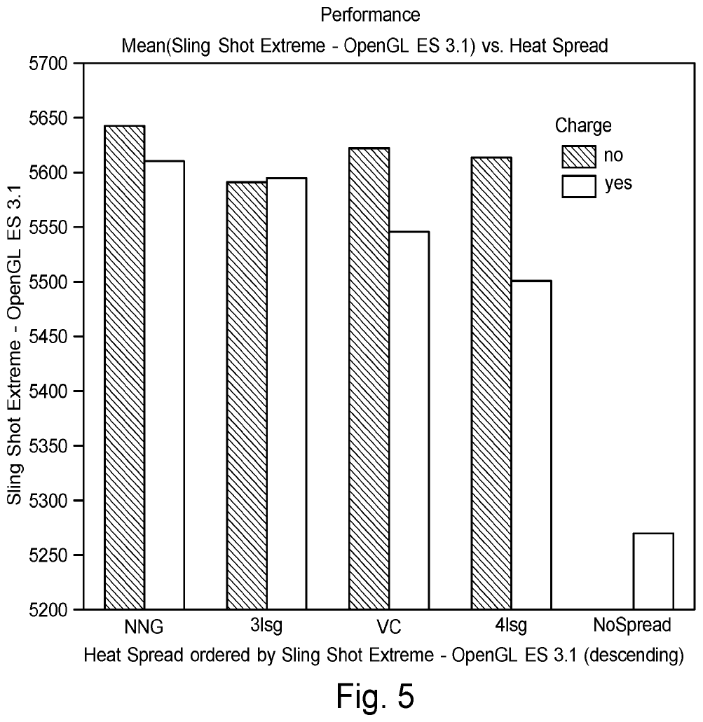

Regarding FIG. 5, the performance of the Device was compared. As shown in FIG. 5, like minimizing the screen temperature, the test sample exhibited the best mean performance for both normal operations and charging based on several runs. Also similar to the results with the screen temperature, one would think that the test sample and the four (4) layer synthetic graphite would exhibit similar results having a similar amount of graphite. As is evident according to FIG. 5, in each instance this is not the case.

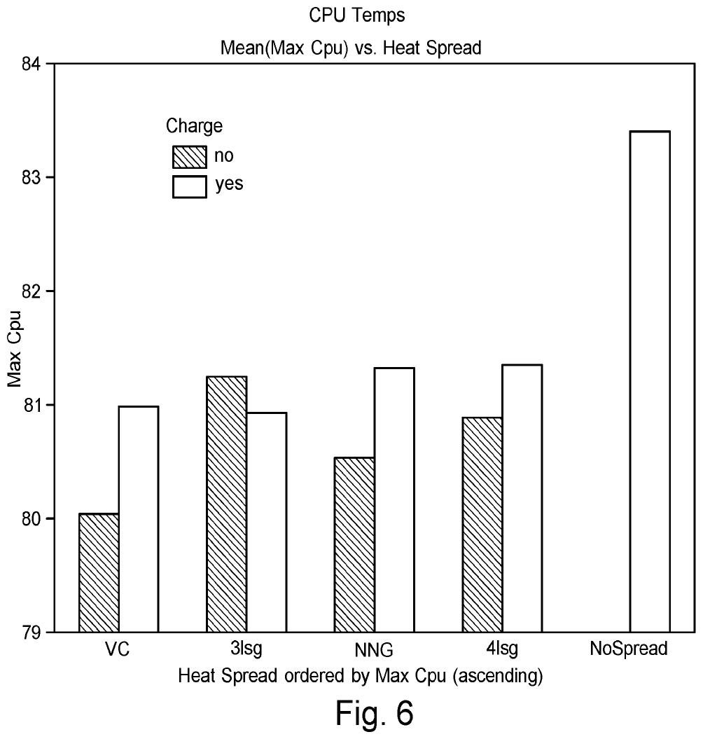

With respect to FIG. 6, dissipating heat from the CPU was the only instance in which an OEM control, the vapor chamber (VC), out-performed the passive thermal management systems of the test sample and the two (2) control stack-ups (3/sg and 4/sg) according to the mean (maximum) CPU temperature measured over several runs. Of the other experiments, the test sample was the best in dissipating heat from the CPU during normal operation.

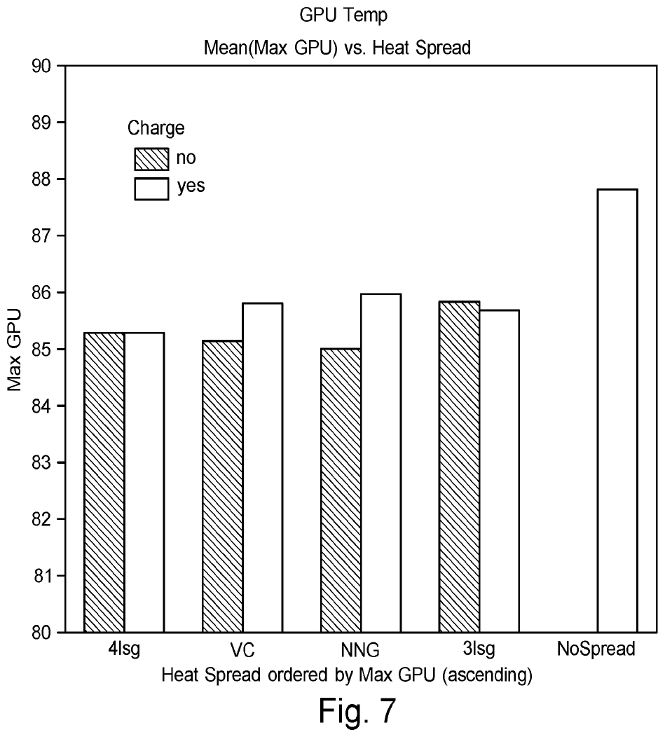

As for FIG. 7, the test sample does the best at dissipating heat from the GPU during normal operation but is on the opposite end of the spectrum during charging (having just slightly the highest mean temperature during charging). It is also interesting how consistent the three layer and four layer stack up controls (3/sg and 4/sg, respectively) are between normal operation and charging with respect to dissipating heat from the GPU. Regarding these two (2) control samples, the process operation of normal operating or charging while operating seems to have little effect over dissipating heat from GPU.

All such weights as they pertain to listed ingredients are based on the active level and, therefore, do not include solvents or by-products that may be included in commercially available materials, unless otherwise specified.

All references to singular characteristics or limitations of the present disclosure shall include the corresponding plural characteristic or limitation, and vice versa, unless otherwise specified or clearly implied to the contrary by the context in which the reference is made. Thus, in the present disclosure, the words “a” or “an” are to be taken to include both the singular and the plural. Conversely, any reference to plural items shall, where appropriate, include the singular.

Unless otherwise indicated (e.g., by use of the term “precisely”), all numbers expressing quantities, properties such as molecular weight, reaction conditions, and so forth as used in the specification and claims are to be understood as being modified in all instances by the term “about.” Accordingly, unless otherwise indicated, the numerical properties set forth in the following specification and claims are approximations that may vary depending on the desired properties sought to be obtained in embodiments of the present invention.

Unless indicated otherwise, thermal conductivities are provided at room temperature and standard pressure (1 atm) or alternatively at the appropriate testing conditions if a standard testing protocol is known such as Angstrom's method, ASTM E1225, and/or ASTM D 5470.

All combinations of method or process steps as used herein can be performed in any order, unless otherwise specified or clearly implied to the contrary by the context in which the referenced combination is made.

All ranges and parameters, including but not limited to percentages, parts, and ratios, disclosed herein are understood to encompass any and all sub-ranges assumed and subsumed therein, and every number between the endpoints. For example, a stated range of “1 to 10” should be considered to include any and all subranges between (and inclusive of) the minimum value of 1 and the maximum value of 10; that is, all subranges beginning with a minimum value of 1 or more (e.g., 1 to 6.1), and ending with a maximum value of 10 or less (e.g., 2.3 to 9.4, 3 to 8, 4 to 7), and finally to each number 1, 2, 3, 4, 5, 6, 7, 8, 9, and 10 contained within the range.

The thermal management system and electronic device of the present disclosure can comprise, consist of, or consist essentially of the essential elements and limitations of the disclosure as described herein, as well as any additional or optional ingredients, components, or limitations described herein or otherwise useful in thermal management systems and/or electronic devices.

To the extent that the terms “include,” “includes,” or “including” are used in the specification or the claims, they are intended to be inclusive in a manner similar to the term “comprising” as that term is interpreted when employed as a transitional word in a claim. Furthermore, to the extent that the term “or” is employed (e.g., A or B), it is intended to mean “A or B or both A and B.” When the Applicant intends to indicate “only A or B but not both,” then the term “only A or B but not both” will be employed. Thus, use of the term “or” herein is the inclusive, and not the exclusive use.

In some embodiments, it may be possible to utilize the various inventive concepts in combination with one another. Additionally, any particular element recited as relating to a particularly disclosed embodiment should be interpreted as available for use with all disclosed embodiments, unless incorporation of the particular element would be contradictory to the express terms of the embodiment. Additional advantages and modifications will be readily apparent to those skilled in the art. Therefore, the disclosure, in its broader aspects, is not limited to the specific details presented therein, the representative apparatus, or the illustrative examples shown and described. Accordingly, departures may be made from such details without departing from the spirit or scope of the general inventive concepts.

1. An electronic device comprising a thermal management system including a graphite element having a thickness of at least about 150 microns, a thermal conductivity of at least about 700 W/mK and devoid of an internal adhesive, the thermal management system in operative contact with a heat source, the heat source comprises more than one electronic component, the more than one electronic component disposed on a stacked motherboard.

2. The electronic device of claim 1 wherein the device having a thickness of no more than 15 mm.

3. (canceled)

4. The electronic device of claim 1, wherein the device has a first user interface on a first major surface of the device and a second user interface on a second major surface of the device.

5-8. (canceled)

9. The electronic device of claim 1, wherein the thermal management system having a substantially planar main body and devoid of a portion of the thermal management system extending away from the planar main body in a direction outside of the plane of the main body.

10. The electronic device of claim 1, wherein the graphite element having a diffusivity of more than 3.8 cm²/s.

11. The electronic device of claim 1, wherein the thermal management system is adhered to at least one of the electronic components.

12. The electronic device of claim 1, wherein a surface area of a portion of the thermal management system adjacent the heat source is larger than a surface area of the heat source.

13. The electronic device of claim 1, wherein the thermal management system is devoid of a fan, heat pipe, a vapor chamber, and an active cooling medium.

14. (canceled)

15. The electronic device of claim 1, wherein the thermal management system having a first major surface adjacent to the heat source and in operative contact with the heat source, the first major surface having a first portion in direct operative contact with heat source and a second portion not in direct operative contact with the heat source, wherein the surface area of the second portion comprises at least 10 percent of the surface area of the heat source.

16-20. (canceled)

21. An electronic device comprising a thermal management system including a graphite element having a thickness of at least about 150 microns, a thermal conductivity of at least about 700 W/mK and devoid of an internal adhesive, the thermal management system in operative contact with a heat source in the device, wherein a thickness of the device comprises no more than 15 mm.

22. The electronic device of claim 21 wherein the device having a thickness of no more than 10 mm.

23. (canceled)

24. The electronic device of claim 21, wherein the device has a first user interface on a first major surface of the device and a second user interface on a second major surface of the device.

25-28. (canceled)

29. The electronic device of claim 21, wherein the thermal management system having a substantially planar main body and devoid of a portion of the thermal management system extending away from the planar main body in a direction outside of the plane of the main body.

30. The electronic device of claim 21, wherein the graphite element having a diffusivity of more than 3.8 cm²/s.

31. The electronic device of claim 21, wherein the thermal management system is adhered to at least one of the electronic components.

32. The electronic device of claim 21, wherein a surface area of a portion of the thermal management system adjacent the heat source is larger than a surface area of the heat source.

33. The electronic device of claim 21, wherein the thermal management system is devoid of a fan, heat pipe, a vapor chamber, and an active cooling medium.

34. (canceled)

35. The electronic device of claim 21, wherein the thermal management system having a first major surface adjacent to the heat source and in operative contact with the heat source, the first major surface having a first portion in direct operative contact with heat source and a second portion not in direct operative contact with the heat source, wherein the surface area of the second portion comprises at least 10 percent of the surface area of the heat source.

36-40. (canceled)

41. An electronic device comprising a thermal management system including a graphite element having a thickness of at least about 150 microns, a thermal conductivity of at least about 700 W/mK and devoid of an internal adhesive, the thermal management system devoid of an additional heat dissipation element, the thermal management system in operative contact with a heat source, the heat source comprises more than one electronic component, the more than one electronic component disposed on a stacked motherboard.

42. The electronic device of claim 41 wherein a thickness of the device comprises less than 15 mm.
